(19) United States
(12) Patent Application Publication
(10) Pub. No.: US 2023/0154957 A1
(43) Pub. Date: May 18, 2023

(54) STRUCTURE OF AN ANGULAR FILTER ON A CMOS SENSOR

(71) Applicant: ISORG, Limoges CEDEX 3 (FR)

(72) Inventors: Benjamin BOUTHINON, GRENOBLE (FR); Pierre MULLER, GRENOBLE (FR); Noémie BALLOT, GRENOBLE (FR)

(21) Appl. No.: 17/798,859

(22) PCT Filed: Feb. 9, 2021
(86) PCT No.: PCT/EP2021/053011

§ 371 Date: Aug. 10, 2022

(30) Foreign Application Priority Data
Feb. 18, 2020 (FR) FR2001613

(51) Int. Cl. H01L 27/146

(52) U.S. Cl. CPC H01L 27/14627; H01L 27/14643

(57) ABSTRACT

A device having a stack includes an image sensor in MOS technology adapted to detect a radiation; a first lens array; a structure formed of at least a first matrix of openings delimited by walls opaque to the radiation; and a second lens array.

The present patent application claims the priority benefit of French patent application FR2001613 which is herein incorporated by reference.

### FIELD

The present disclosure generally concerns an image acquisition device.

### BACKGROUND

An image acquisition device generally comprises an image sensor and an optical system. The optical system may be an angular filter, or a set of lenses, interposed between the sensitive portion of the sensor and the object to be imaged.

The image sensor generally comprises an array of photodetectors capable of generating a signal proportional to the received light intensity.

An angular filter is a device enabling to filter an incident radiation according to the incidence of this radiation and thus to block rays having an incidence greater than a desired angle, called maximum incidence angle, which enables to form a sharp image of the object to be imaged on the sensitive portion of the image sensor.

### SUMMARY

There is a need to improve image acquisition devices.

An embodiment overcomes all or part of the disadvantages of known image acquisition devices.

An embodiment provides a device comprising a stack comprising, in the order, at least:
an image sensor in MOS technology adapted to detecting a radiation;
a first array of lenses;
a structure formed of at least a first matrix of openings delimited by walls opaque to said radiation; and
a second array of lenses.

According to an embodiment, the number of lenses of the second array is greater than the number of lenses of the first array.

According to an embodiment, the number of lenses of the second array is from two to ten times greater than the number of lenses of the first array, preferably, twice greater.

According to an embodiment, the device comprises an adhesive layer between said structure and the first array of lenses.

According to an embodiment, the device comprises a refraction index matching layer between said structure and the first array of lenses.

According to an embodiment:
each opening of the first matrix is associated with a single lens of the second array; and
the optical axis of each lens of the second array is aligned with the center of an opening of the first matrix.

According to an embodiment, the structure comprises, under the first matrix of openings, a second matrix of openings, delimited by walls opaque to said radiation. The number of openings of the first matrix is identical to the number of openings of the second matrix. The center of each opening of the first matrix is aligned with the center of an opening of the second matrix.

According to an embodiment, the lenses of the second array and the lenses of the first array are plano-convex. The planar surfaces of the lenses of the first array and of the second array are on the sensor side.

According to an embodiment, the openings are filled with a material at least partly transparent to said radiation.

According to an embodiment, the lenses of the first array have a diameter greater than the diameter of the lenses of the second array.

According to an embodiment, the structure comprises a third array of plano-convex lenses, the planar surfaces of the lenses of the second lens array and of the third lens array facing one another. The third lens array is located between the first matrix of openings and the first lens array or between the first matrix of openings and the second lens array.

According to an embodiment, the optical axis of each lens of the second array is aligned with the optical axis of a lens of the third array.

According to an embodiment, the image focal planes of the lenses of the second array coincide with the object focal planes of the lenses of the third array.

According to an embodiment, the number of lenses of the third array is greater than the number of lenses of the second array.

According to an embodiment, the lenses of the second array have a diameter greater than that of the lenses of the third array.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows in a partial simplified block diagram an example of an image acquisition system;

FIG. 2 shows in a partial simplified cross-section view an example of an image acquisition device;

FIG. 3 shows in a partial simplified cross-section view an embodiment of the image acquisition device illustrated in FIG. 2;

FIG. 4 shows in a partial simplified cross-section view another embodiment of the image acquisition device illustrated in FIG. 2;

FIG. 5 shows in a partial simplified cross-section view still another embodiment of the image acquisition device illustrated in FIG. 2;

FIG. 6 shows in a partial simplified cross-section view still another embodiment of the image acquisition device illustrated in FIG. 2;

FIG. 7 shows in a partial simplified cross-section view still another embodiment of the image acquisition device illustrated in FIG. 2; and

FIG. 8 shows in a partial simplified cross-section view still another embodiment of the image acquisition device illustrated in FIG. 2.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the structure of the image sensor will not be precisely detailed in the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following description, unless specified otherwise, a layer or a film is called opaque to a radiation when the transmittance of the radiation through the layer of the film is smaller than 10%. In the rest of the disclosure, a layer or a film is called transparent to a radiation when the transmittance of the radiation through the layer or the film is greater than 10%, preferably greater than 50%. According to an embodiment, for a same optical system, all the elements of the optical system which are opaque to a radiation have a transmittance which is smaller than half, preferably smaller than one fifth, more preferably smaller than one tenth, of the lowest transmittance of the elements of the optical system transparent to said radiation. In the rest of the disclosure, the expression “useful radiation” designates the electromagnetic radiation crossing the optical system in operation.

In the following description, the expression “micrometer-range optical element” designates an optical element formed on a surface of a support having its maximum dimension, measured parallel to said surface, greater than 1 μm and smaller than 1 mm.

Embodiments of optical systems will not be described for optical systems comprising an array of micrometer-range optical elements in the case where each micrometer-range optical element corresponds to a micrometer-range lens, or microlens, formed of two diopters. It should however be clear that these embodiments may also be implemented with other types of micrometer-range optical elements, where each micrometer-range optical element may for example correspond to a micrometer-range Fresnel lens, to a micrometer-range index gradient lens, or to a micrometer-range diffraction grating.

In the following description, “visible light” designates an electromagnetic radiation having a wavelength in the range from 400 nm to 700 nm and “infrared radiation” designates an electromagnetic radiation having a wavelength in the range from 700 nm to 1 mm. In infrared radiation, one can particularly distinguish near infrared radiation having a wavelength in the range from 700 nm to 1.7 μm.

In the following description, the refraction index of a material corresponds to the refraction index of the material for the wavelength range of the radiation captured by the image sensor. Unless specified otherwise, the refraction index is considered as substantially constant over the wavelength range of the useful radiation, for example, equal to the average of the refraction index over the wavelength range of the radiation captured by the image sensor.

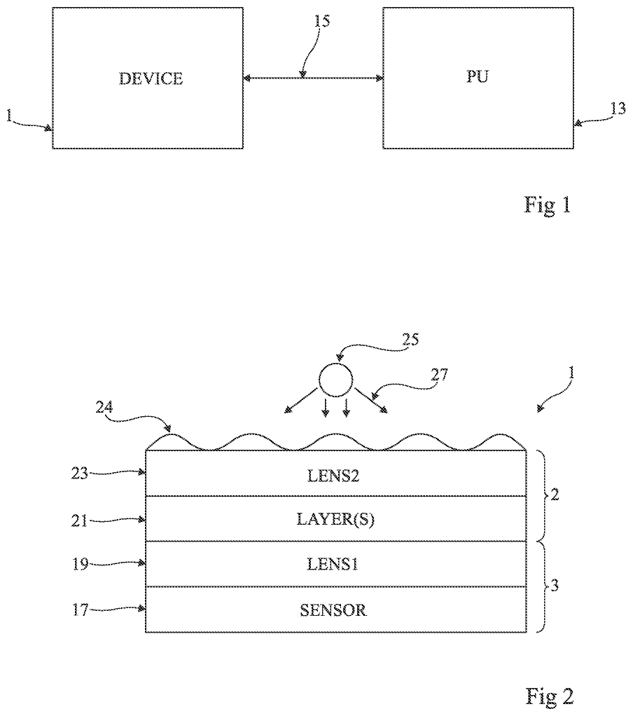

FIG. 1 shows in a partial simplified block diagram an example of an image acquisition system.

The image acquisition system, illustrated in FIG. 1, comprises:

a. an image acquisition device 1 (DEVICE); and

b. a processing unit 13 (PU).

Processing unit 13 preferably comprises means for processing the signals delivered by device 1, not shown in FIG. 1. Processing unit 13 for example comprises a microprocessor.

Device 1 and processing unit 13 are preferably coupled by a link 15. Device 1 and the processing unit are for example integrated in a same circuit.

FIG. 2 shows in a partial simplified cross-section view an example of an image acquisition device 1.

More particularly, FIG. 2 shows image acquisition device 1 and a source 25 emitting a radiation 27.

Image acquisition device 1, illustrated in FIG. 2, comprises from bottom to top:
an image sensor 17 (SENSOR) in complementary metal oxide semiconductor (CMOS) technology, which may be coupled to photodetectors or inorganic (polysilicon) or organic photodiodes adapted to detecting radiation 27;
a first array of lenses 19 (LENS1);
an array structure 21 (LAYER(S));
a second array of lenses 23 (LENS2); and
an object 24.

Structure 21 and second lens array 23 preferably form an optical filter 2 or angular filter. Image sensor 17 and first lens array 19 preferably form a CMOS imager 3.

Radiation 27 is for example in the visible range and/or in the infrared range. It may be a radiation of a single wavelength or a radiation of a plurality of wavelengths (or wavelength range).

Light source 25 is illustrated, in FIG. 2, above object 24. It may however as a variant be located between object 24 and filter 2.

In the case of an application to the determination of fingerprints, object 24 corresponds to a user's finger.

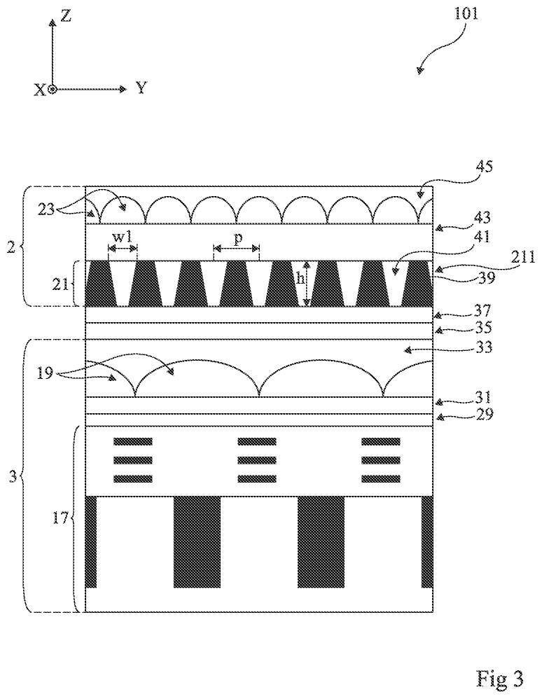

FIG. 3 shows in a partial simplified cross-section view an embodiment of the image acquisition device illustrated in FIG. 2.

More particularly, FIG. 3 shows an image acquisition device 101 in which array structure 21 is formed of a layer 211 comprising a first matrix of openings 41 delimiting walls 39 opaque to said radiation.

Image acquisition device 101, illustrated in FIG. 3, comprises from bottom to top:
CMOS imager 3, formed of:
   image sensor 17 (not detailed in the drawings) preferably formed of a substrate, of readout circuits, of conductive tracks, and of photodiodes,
   a first passivation (insulating) layer 29 on top of and in contact with image sensor 17,
   a second layer 31 playing the role of a color filter covering first layer 29 full plate, and
   first plano-convex lens array 19, having its planar surfaces on the side of sensor 17, covered with a third passivation layer 33;
a fourth optical index matching layer 35 covering layer 33;
a fifth layer 37 or adhesive on top of and in contact with layer 35; and
angular filter 2 formed of:
   structure 21 comprising layer 211 of openings 41 and having its walls 39 on top of and in contact with fifth layer 37,
   a substrate 43 covering structure 21, and
   second plano-convex lens array 23, having its planar surfaces on the sensor side, covered with a sixth layer 45.

First lens array 19 for example enables to focus the rays incident to lenses 19 onto the photodetectors present in image sensor 17.

According to an embodiment, the lens array 19 within imager 3 forms a pixel array where a pixel corresponds, for example, substantially to the square having the circle corresponding to the surface of a lens 19 inscribed therein. Each pixel thus comprises a lens 19 substantially centered on the pixel. For example, all lenses 19 have substantially the same diameter. The diameter of lenses 19 is preferably substantially identical to the length of the pixel sides.

According to an embodiment, the pixels of CMOS imager 3 are substantially square. The length of the pixel sides is preferably in the range from 0.7 μm to 50 μm and is more preferably in the order of 30 μm.

According to an embodiment, imager 3 is substantially square. The length of the sides of imager 3 is preferably in the range from 5 mm to 50 mm, and is more preferably in the order of 10 mm.

Layer 31 is preferably made of a material absorbing wavelengths in the range from approximately 400 nm to 600 nm (cyan), preferably from 470 nm to 600 nm (green).

Layer 29 may be made of an inorganic material, for example, of silicon oxide (SiO₂), of silicon nitride (SiN), or of a combination of these two materials (for example, a multilayer stack).

Insulating layer 29 may be made of a fluorinated polymer, particularly Bellex's fluorinated polymer known under trade name “Cytop”, of polyvinylpyrrolidone (PVP), of polymethyl methacrylate (PMMA), of polystyrene (PS), of parylene, of polyimide (PI), of acrylonitrile butadiene styrene (ABS), of poly(ethylene terephthalate) (PET), of poly(ethylene naphthalate) (PEN), of cyclo olefin polymer (COP), of polydimethylsiloxane (PDMS), of a photolithography resin, of epoxy resin, of acrylate resin, or of a mixture of at least two of these compounds.

As a variant, layer 29 may be made of an inorganic dielectric, particularly of silicon nitride, of silicon oxide, or of aluminum oxide (Al₂O₃).

Layer 33 is preferably a passivation layer which takes the shape of microlenses 19 and which enables to insulate and planarize the surface of imager 3. Layer 33 may be made of an inorganic material, for example, of silicon oxide (SiO₂) or of silicon nitride (SiN), or of a combination of these two materials (for example, a multilayer stack).

According to the embodiment illustrated in FIG. 3, optical filter 2, by the association of the second array of lenses 23 and of layer 211, is adapted to filtering the incident radiation according to its angle of incidence relative to the optical axes of the lenses 23 of the second array.

According to the embodiment illustrated in FIG. 3, angular filter 2 is adapted so that the photodetectors of image sensor 17 only receive rays having respective incidences, relative to the optical axes of lenses 23, smaller than a maximum angle of incidence smaller than 45°, preferably smaller than 20°, more preferably smaller than 5°, more preferably still smaller than 3°. Angular filter 2 is capable blocking the rays of the incident radiation having respective incidences relative to the optical axes of the lenses 23 of filter 2 greater than the maximum incidence angle.

According to the embodiment illustrated in FIG. 3, each opening 41 of layer 211 is associated with a single lens 23 of the second array and each lense 23 is associated with a single opening 41. Lenses 23 preferably meet. The optical axes of lenses 23 are preferably aligned with the centers of openings 41. The diameter of the lenses 23 of the second array is preferably greater than the maximum cross-section (measured perpendicularly to the optical axis of lenses 23) of openings 41.

Walls 39 are for example opaque to radiation 27, for example, absorbing and/or reflective for radiation 27. Walls 39 are preferably opaque for wavelengths in the range from 400 nm to 600 nm (cyan and green), used for imaging (biometry and fingerprint imaging). Call “h” the height of walls 39 (measured in a plane parallel to the optical axes of lenses 23).

According to an embodiment, openings 41 are arranged in rows and in columns. Openings 41 may have substantially the same dimensions. Call “w1” the diameter of openings 41 (measured at the base of the openings, that is, at the interface with substrate 43). The diameter of each lens 23 is preferably greater than the diameter w1 of the opening 41 having lens 23 associated therewith.

According to an embodiment, openings 41 are regularly arranged in rows and in columns. Call “p” the repetition pitch of openings 41, that is, the distance in top view between centers of two successive openings 41 of a row or of a column.

In FIG. 3, openings 41 are shown with a trapezoidal cross-section. Generally, openings 41 may be square, triangular, rectangular, funnel-shaped. In the shown example, the width (or diameter) of openings 41, at the level of the upper surface of layer 211, is greater than the width (or diameter) of openings 41, at the level of the lower surface of layer 211.

Openings 41, in top view, may be circular, oval, or polygonal, for example, triangular, square, rectangular, or trapezoidal. Openings 41, in top view, are preferably circular.

The resolution of optical filter 2, in cross-section (plane XZ or YZ), is preferably greater than the resolution of image sensor 17, preferably from two to ten times greater. In other words, there are, in cross-section (plane XZ or YZ), from two to ten times more openings 41 than lenses 19 of the first array. Thus a lens 19 is associated with at least four openings 41 (two openings in plane YZ and two openings in plane XZ).

An advantage is that the difference between the resolution of imager and that of angular filter 2 enables to decrease the constraints of alignment of filter 2 on imager 3.

For example, lenses 23 have substantially the same diameter. The diameter of the lenses 19 of the first array is thus greater than the diameter of the lenses 23 of the second array.

Width w1 is, in practice and preferably, smaller than the diameter of lenses 23 so that layer 39 has a sufficient bonding to substrate 43. Width w1 is preferably in the range from 0.5 μm to 25 μm, for example equal to approximately 10 μm. Pitch p may be in the range from 1 μm to 25 μm, preferably in the range from 12 μm to 20 μm. Height h is, for example, in the range from 1 μm to 1 mm, preferably in the range from 12 μm to 15 μm.

According to this embodiment, microlenses 23 and substrate 43 are preferably made of materials which are transparent or partially transparent, that is, transparent in a portion of the considered spectrum for the targeted field, for example, imaging, over the wavelength range corresponding to the wavelengths used during the exposure.

Substrate 43 may be made of a transparent polymer which does not absorb at least the considered wavelengths, here in the visible and infrared range. The polymer may in particular be made of polyethylene terephthalate PET, poly(methyl methacrylate) PMMA, cyclic olefin polymer (COP), a polyimide (PI), or of polycarbonate (PC). Substrate 43 is preferably made of PET. The thickness of substrate 43 may for example vary from 1 to 100 μm, preferably from 10 to 50 μm. Substrate 43 may correspond to a colored filter, to a polarizer, to a half-wave plate or to a quarter-wave plate.

According to an embodiment, microlenses 23 and 19 are made of materials having a refraction index in the range from 1.4 to 1.7 and preferably in the order of 1.6. Microlenses 23 and 19 may be made of silica, of PMMA, of a positive resist, of PET, of polyethylene naphthalate (PEN), of COP, of polydimethylsiloxane (PDMS)/silicone, of epoxy resin, or of acrylate resin. Microlenses 23 and 19 may be formed by flowing of resist blocks. Microlenses 19 and 23 may further be formed by molding on a layer of PET, PEN, COP, PDMS/silicone, of epoxy resin, or of acrylate resin. Microlenses 19 and 23 may finally be formed by nano-imprint.

As a variant, each microlens is replaced with another type of micrometer-range optical element, particularly a micrometer-range Fresnel lens, a micrometer-range index gradient lens, or micrometer-range diffraction grating. The microlenses are converging lenses, each having a focal distance f in the range from 1 μm to 100 μm, preferably from 1 μm to 50 μm. According to an embodiment, all microlenses 19 are substantially identical and all microlenses 23 are substantially identical.

According to an embodiment, layer 45 is a filling layer which follows the shape of microlenses 23. Layer 45 may be obtained from an optically clear adhesive (OCA), particularly a liquid optically clear adhesive (LOCA), or a material with a low refraction index, or an epoxy/acrylate glue, or a film of a gas or of a gaseous mixture, for example, air.

Preferably, layer 45 is made of a material having a low refraction index, smaller than that of the material of microlenses 23. For example, the difference between the refraction index of the material of lenses 23 and the refraction index of the material of layer 45 is preferably in the range from 0.5 to 0.1. The difference between the refraction index of the material of lenses 23 and the refraction index of the material of layer 45 is more preferably in the order of 0.15. Layer 45 may be made of a filling material which is a non-adhesive transparent material.

According to another embodiment, layer 45 corresponds to a film which is applied against microlens array 23, for example an OCA film. In this case, the contact area between layer 45 and microlenses 23 may be decreased, for example, limited to the tops of microlenses 23.

According to an embodiment, openings 41 are filled with air or with a filling material at least partially transparent to the radiation detected by the photodetectors, for example, PDMS, an epoxy or acrylate resin, or a resin known under trade name SU8. As a variant, openings 41 may be filled with a partially absorbing material, that is, a material absorbing in a portion of the considered spectrum for the targeted field, for example, imaging, to chromatically filter the rays angularly filtered by filter 2. As a variant, the filling material of openings 41 is opaque to radiation in near infrared. In the case where openings 41 are filled with a material, said material may for example form a layer between walls 39 and the underlying layer 37 so that walls 39 are not in contact with layer 37.

Angular filter 2 preferably has a thickness in the order of 50 μm.

Angular filter 2 and imager 3 are for example assembled by an adhesive layer 37. Layer 37 is for example made of a material selected from an acrylate glue, an epoxy glue, or an OCA. Layer 37 is preferably made of an acrylate glue.

Layer 35 is a refraction index matching layer, that is, it enables to decrease losses of light rays by reflection at the interface between the angular filter (the filling material of openings 41) and passivation layer 33. Layer 35 is preferably made of a material having a refraction index between the refraction index of layer 33 and the refraction index of the filling material of openings 41.

According to an implementation mode, layer 35 is deposited on the front surface of imager 3 (the upper surface in the orientation of FIG. 3) by printing, by transfer of a film (lamination), or by evaporation, at the end of the manufacturing of imager 3.

According to an implementation mode, layer 37 is deposited on the rear surface of angular filter 2 (the lower surface in the orientation of FIG. 3) by printing or by transfer of a film (lamination).

As variant, layer 37 is deposited on the front surface of layer 35 of imager 3.

The assembly of filter 2 and of imager 3 is for example performed after the deposition of layer 37 by lamination of filter 2 at the surface of imager 3 (more particularly on the surface of layer 35).

According to an implementation mode, a step of anneal, of ultraviolet crosslinking, or of autoclave pressurization, follows the assembly to optimize the mechanical bonding properties.

According to an embodiment, not shown in FIG. 3, device 101 comprises an additional layer, for example, between filter 2 and imager 3. This layer corresponds to an infrared filter enabling to filter radiations having a wavelength greater than 600 nm. The transmittance of this infrared filter is preferably smaller than 0.1% (OD3 (Optical Density of 3)).

According to the considered materials, the method of forming at least certain layers may correspond to a so-called additive process, for example, by direct printing of the material forming the layers at the desired locations, particularly in sol-gel form, for example, by inkjet printing, photogravure, silk-screening, flexography, spray coating, or drop casting.

According to the considered materials, the method of forming at least certain layers may correspond to a so-called subtractive method, where the material forming the layers is deposited over the entire structure and where the non-used portions are then removed, for example, by photolithography or laser ablation.

According to the considered material, the deposition over the entire structure may be performed, for example, by liquid deposition, by cathode sputtering, or by evaporation. Methods such as spin coating, spray coating, heliography, slot-die coating, blade coating, flexography, or silk-screening, may in particular be used. When the layers are metallic, the metal is for example deposited by evaporation or by cathode sputtering over the entire support and the metal layers are delimited by etching.

Advantageously, at least some of the layers may be formed by printing techniques. The materials of the previously-described layers may be deposited in liquid form, for example, in the form of conductive and semiconductor inks by means of inkjet printers. “Materials in liquid form” here also designates gel materials capable of being deposited by printing techniques. Anneal steps may be provided between the depositions of the different layers, but it is possible for the anneal temperatures not to exceed 150° C., and the deposition and the possible anneals may be carried out at the atmospheric pressure.

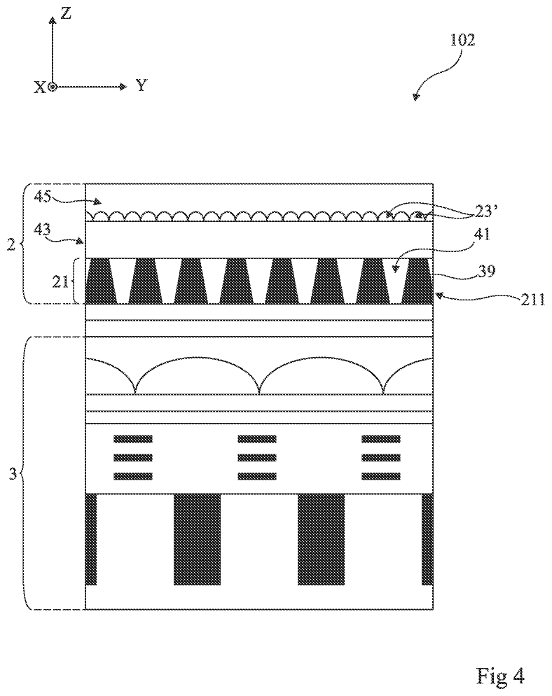

FIG. 4 shows in a partial simplified cross-section view another embodiment of the image acquisition device illustrated in FIG. 2.

More particularly, FIG. 4 shows an image acquisition device 102 similar to the image acquisition device 101 illustrated in FIG. 3, with the difference that the array of second lenses comprises lenses 23′ smaller than lenses 23 (FIG. 3).

The number of lenses 23′ in device 102 is preferably greater than the number of openings 41 (in plane XY). As an example, the number of lenses 23′ is four times greater than the number of openings 41. Lenses 23′ have, according to the embodiment illustrated in FIG. 4, a diameter smaller than the diameter w1 of openings 41.

An advantage of the embodiment illustrated in FIG. 4 is that it requires no alignment of the second array of lenses 23′ on the matrix of openings 41.

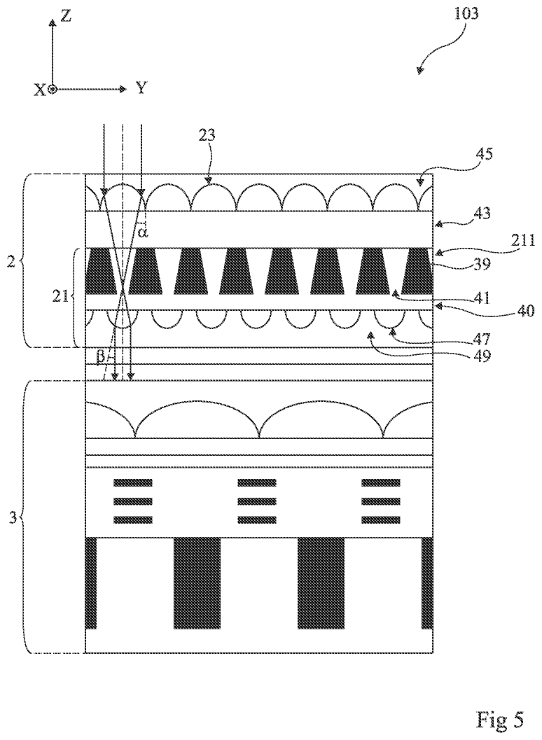

FIG. 5 shows in a partial simplified cross-section view still another embodiment of the example of the image acquisition device illustrated in FIG. 2.

More particularly, FIG. 5 shows an image acquisition device 103 similar to the image acquisition device 101 illustrated in FIG. 3, with the difference that array structure 21 comprises a third lens array 47.

The third array of plano-convex lenses 47 is used for the collimation of the light transmitted by the matrix of openings 41 coupled to the second lens array 23. The planar surfaces of lenses 47 face the planar surfaces of lenses 23. The third array is located between layer 211 and imager 3.

In the embodiment shown in FIG. 5, the number of lenses 47 of the third array is equal to the number of lenses 23 of the second array. The lenses 47 of the third array and the lenses 23 of the second array are aligned by their optical axes.

As a variant, the number of lenses 47 of the third array is more significant than the number of levels 23 of the second array.

Lenses 47 meet or not.

The rays emerge from lenses 23 and from layer 211 with an angle α relative to the respective direction of the rays incident to lenses 23. Angle α is specific to a lens 23 and depends on the diameter thereof and on the focal distance of this same lens 23.

As they come out of layer 211, the rays meet the lenses 47 of the third array. The rays are thus deviated, as they come out of lenses 47, by an angle β relative to the respective directions of the rays incident to lenses 47. Angle β is specific to a lens 47 and depends on the diameter thereof and on the focal distance of this lens 47.

A total divergence angle corresponds to the deviations successively generated by lenses 23 and by lenses 47. The lenses 47 of the third array are selected so that the total divergence angle is for example smaller than or equal to approximately 5°.

The embodiment shown in FIG. 5 illustrates an ideal configuration where the image focal planes of the lenses 23 of the second array are the same as the object focal planes of the lenses 47 of the third array. The shown rays, arriving parallel to the optical axis, are focused on the image focus of lens 23 or object focus of lens 47. The rays which emerge from lens 47 thus propagate parallel to the optical axis thereof. The total divergence angle is, in this case, zero.

Third lens array 47 is, in FIG. 5, located under and in contact with a seventh layer 40. Seventh layer 40, originating from the filling of openings 41, covers the rear surfaces of walls 39.

As a variant, the third array of lenses 47 is located on top of and in contact with the rear surface of walls 39. Openings 41 are then filled with air or with a filling material.

Lenses 47 and lenses 23 have the same composition or different compositions.

According to the embodiment of FIG. 5, the rear surface of lenses 47 is covered with an eighth filling layer 49. Layer 49 and layer 45 may have the same composition or different compositions. Layer 49 preferably has a refraction index smaller than the refraction index of the material of lenses 47.

In the absence of a third lens array 47, if the divergence angle is too large, the rays emerging from a lens 23 would risk illuminating a plurality of photodetectors or pixels. This generates a loss of resolution in the quality of the resulting image.

An advantage that appears is that the presence of a third array of lenses 47 generates a decrease in the divergence angle at the output of angular filter 2. The decrease of the divergence angle enables to decrease risks of intersection of the rays emerging at the level of imager 3.

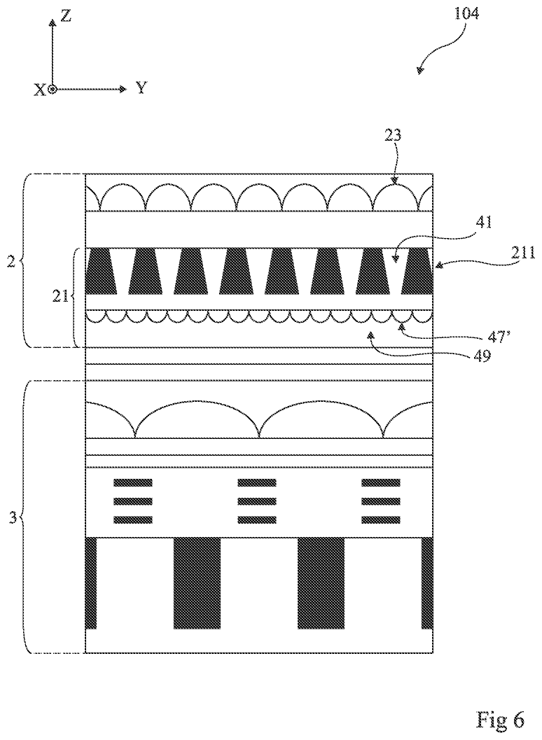

FIG. 6 shows in a partial simplified cross-section view still another embodiment of the example of the image acquisition device illustrated in FIG. 2.

More particularly, FIG. 6 shows an image acquisition device 104 similar to the image acquisition device 103 illustrated in FIG. 5, with the difference that it comprises lenses 47′ smaller than lenses 47 (FIG. 5).

The number of lenses 47′ in device 104 is preferably greater than the number of openings 41. As an example, the number of lenses 47′ is four times greater than the number of openings 41 (in plane XY).

An advantage of the embodiment illustrated in FIG. 6 is that it requires no alignment of third lens array 47′ on the matrix of openings 41.

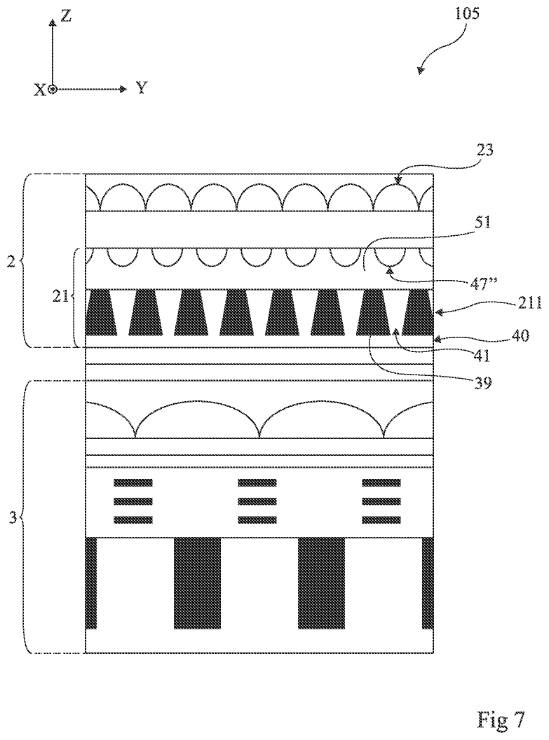

FIG. 7 shows in a partial simplified cross-section view still another embodiment of the example of the acquisition device illustrated in FIG. 2.

More particularly, FIG. 7 shows an image acquisition device 105 similar to the image acquisition device 103 illustrated in FIG. 5, with the difference that third lens array 47″ is located between second lens array 23 and layer 211 of openings 41.

In the shown example, device 105 comprises a filling layer 51 covering the rear surface of lenses 47. Layer 51 is similar to the layer 49 of the device 103 illustrated in FIG. 5, with the difference that it rests on the upper surface of layer 211.

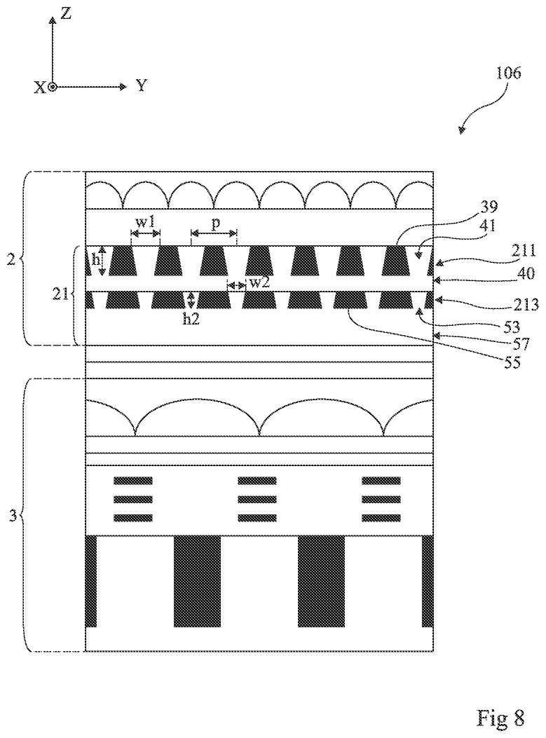

FIG. 8 shows in a partial simplified cross-section view still another embodiment of the example of the acquisition device illustrated in FIG. 2.

More particularly, FIG. 8 shows an image acquisition device 106 similar to the image acquisition device 101 illustrated in FIG. 3, with the difference that array structure 21 comprises a ninth layer 213 formed of a second matrix of openings 53 delimiting walls 55 opaque to radiation 27 (FIG. 2).

According to the embodiment illustrated in FIG. 8, layer 213 is located under and in contact with the seventh layer 40 resulting from the filling of openings 41 with the filling material. Seventh layer 40 covers the rear surfaces of walls 39.

AS a variant, layer 213 is located on top of and in contact with the rear surface of walls 39. Openings 41 are then filled with air or with a filling material.

Openings 53 for example have substantially the same shape as openings 41, with the difference that the dimensions of openings 41 and 53 may be different. Walls 55 for example have substantially the same shape and the same composition as walls 39, with the difference that the dimensions of walls 39 and 55 may be different.

According to the embodiment illustrated in FIG. 8, layer 213 comprises a number of openings 53 substantially identical to the number of openings 41 present in the matrix of layer 211. Preferably, the number of openings 41 is identical to the number of openings 53. Each opening 41 is preferably aligned with an opening 53, for example, the center of each opening 41 is aligned with the center of an opening 53.

According to an embodiment, openings 53 and openings 41 have the same dimensions, that is, openings 53 have a diameter “w2” (measured at the base of the openings, that is, at the interface with layer 40) substantially identical to the diameter w1 of openings 41. Preferably, diameters w1 and w2 are identical. Walls 55 for example have a height h2 substantially identical to the height h of walls 39. Preferably, heights h and h2 are identical.

As a variant, diameters w1 and w2 are different. In this case, diameter w2 is, preferably, smaller than diameter w1.

According to another variant, heights h and h2 are different.

According to an embodiment, openings 53 are filled with air or, preferably, with a filling material having a composition similar to that of the filling material of openings 41. More preferably still, the filling material fills openings 53 and forms a layer 57 on the rear surface of walls 55.

Various embodiments and variants have been described.

Those skilled in the art will understand that certain features of these various embodiments and variants may be combined, and other variants will occur to those skilled in the art. In particular, the embodiments illustrated in FIGS. 4 to 8 may be combined. Further, the described embodiments and implementation modes are for example not limited to the examples of dimensions and of materials mentioned hereabove.

Finally, the practical implementation of the described embodiments and variations is within the abilities of those skilled in the art based on the functional indications given hereabove.

1. A device comprising a stack comprising:
an image sensor in MOS technology adapted to detecting a radiation;
a first lens array;
a structure formed of at least a first matrix of openings delimited by walls opaque to said radiation; and
a second lens array, the number of lenses of the second array being greater than the number of lenses of the first array.

2. The device according to claim 1, wherein the number of lenses of the second array is from two to ten times greater than the number of lenses of the first array.

3. The device according to claim 1, further comprising an adhesive layer between said structure and the first lens array.

4. The device according to claim 1, further comprising a refraction index matching layer between said structure and the first lens array.

5. The device according to claim 1, wherein:
each opening of the first matrix is associated with a single lens of the second array; and
the optical axis of each lens of the second array is aligned with the center of an opening of the first matrix.

6. The device according to claim 1, wherein the structure comprises, under the first matrix of openings, a second matrix of openings, delimited by walls opaque to said radiation, the number of openings of the first matrix and the number of openings of the second matrix being identical and the center of each opening of the first matrix being aligned with the center of an opening of the second matrix.

7. The device according to claim 1, wherein the lenses of the second array and the lenses of the first array are plano-convex, the planar surfaces of the lenses of the first array and of the second array are on the sensor side.

8. The device according to claim 1, wherein the openings are filled with a material at least partially transparent to said radiation.

9. The device according to claim 1, wherein the lenses of the first array have a diameter greater than the diameter of the lenses of the second array.

10. The device according to claim 1, wherein the structure comprises a third array of plano-convex lenses, the planar surfaces of the lenses of the second array of lenses and of the third array of lenses facing one another, the third lens array being located between the first matrix of openings and the first lens array or between the first matrix of openings and the second lens array.

11. The device according to claim 10, wherein the optical axis of each lens of the second array is aligned with the optical axis of a lens of the third array.

12. The device according to claim 10, wherein the image focal planes of the lenses of the second array coincide with the object focal planes of the lenses of the third array.

13. The device according to claim 10, wherein the number of lenses of the third array is greater than the number of lenses of the second array.

14. The device according to claim 10, wherein the lenses of the second array have a diameter greater than that of the lenses of the third array.
